(19) United States
(12) Patent Application Publication
(10) Pub. No.: US 2025/0102585 A1
(43) Pub. Date: Mar. 27, 2025

(54) BATTERY ASSEMBLY STATE-OF-CHARGE ESTIMATION

(71) Applicant: GM GLOBAL TECHNOLOGY OPERATIONS LLC, Detroit, MI (US)

(72) Inventors: Yue-Yun Wang, Troy, MI (US); Charles W. Wampler, Birmingham, MI (US); Chen-Fang Chang, Bloomfield Hills, MI (US)

(73) Assignee: GM GLOBAL TECHNOLOGY OPERATIONS LLC, Detroit, MI (US)

(21) Appl. No.: 18/475,363

(22) Filed: Sep. 27, 2023

(51) Int. Cl. G01R 31/388; B60L 58/12; G01R 31/367; G01R 31/3842

(52) U.S. Cl. CPC G01R 31/388; B60L 58/12; G01R 31/367; G01R 31/3842

(57) ABSTRACT

A system for estimating a state-of-charge of a battery assembly includes a sensor cell and an estimator circuit. The sensor cell is coupled in series to the battery assembly. The battery assembly has an assembly battery chemistry and the sensor cell has a sensor battery chemistry, and the assembly battery chemistry is different than the sensor battery chemistry. The estimator circuit is operational to acquire a sequence of current sensor cell state-of-charges based on a sensor cell model and a sequence of sensor voltages across the sensor cell, calculate a sequence of current battery assembly state-of-charges based on the sequence of current sensor cell state-of-charges, and calculate an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

### INTRODUCTION

The present disclosure relates to a system and a method for a battery assembly state-of-charge estimation.

Lithium iron phosphate batteries have a long life and good thermal stability. Therefore, the batteries are suitable for use in electric vehicles and hybrid vehicles. However, the lithium iron phosphate batteries also have a relatively flat open-circuit voltage versus state-of-charge curve. The relatively flat open-circuit voltage makes estimations of a state-of-charge for the batteries difficult, often resulting in up to a 10 percent error.

Accordingly, those skilled in the art continue with research and development efforts in the field of estimating a battery assembly state-of-charge.

### SUMMARY

A system for estimating a state-of-charge of a battery assembly is provided herein. The system includes a sensor cell and an estimator circuit. The sensor cell is coupled in series to the battery assembly. The battery assembly has an assembly battery chemistry, the sensor cell has a sensor battery chemistry, and the assembly battery chemistry is different than the sensor battery chemistry. The estimator circuit is coupled to the battery assembly and the sensor cell. The estimator circuit is operational to acquire a sequence of current sensor cell state-of-charges of the sensor cell based on a sensor cell model of the sensor cell and a sequence of sensor voltages across the sensor cell, calculate a sequence of current battery assembly state-of-charges of the battery assembly based on the sequence of current sensor cell state-of-charges, and calculate an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

In one or more embodiments of the system, the sensor cell model of the sensor cell includes the sequence of current battery assembly state-of-charges as an augmented state variable.

In one or more embodiments of the system, the sequence of current battery assembly state-of-charges is represented by SOC_{BA}(k+1)=(CAP_{SC}/CAP_{BA})(SOC_{SC}(k)−d %)+ (Idt/CAP_{BA}))+ε(k). Where SOC_{BA}(k+1) is the current battery assembly state-of-charge at time k+1, k is a plurality of measurement times, CAP_{SC} is a capacity of the sensor cell, CAP_{BA} is a capacity of the battery assembly, SOC_{SC}(k) is the current sensor cell state-of-charge at time k, d % is a minimum charge offset, Idt is a sum of a current flowing through the battery assembly, and ε(k) is noise model at the time k.

In one or more embodiments of the system, the filtering utilizes an Extended Kalman Filter.

In one or more embodiments of the system, the Extended Kalman Filter is a fast Extended Kalman Filter to calculate the estimated sensor cell state-of-charge.

In one or more embodiments of the system, the estimator circuit is further operational to estimate a capacity degradation coefficient of the sensor cell using the Extended Kalman Filter executed at a slower rate than the fast Extended Kalman Filter.

In one or more embodiments of the system, the assembly battery chemistry is a lithium iron phosphate chemistry, a lithium iron manganese phosphate chemistry, or a sodium ion chemistry.

In one or more embodiments of the system, the sensor battery chemistry is a nickel manganese cobalt chemistry, a nickel cobalt aluminum chemistry, a lithium-ion manganese chemistry, or a lithium cobalt chemistry

In one or more embodiments of the system, the battery assembly is a battery pack or a battery module.

A method for estimating a state-of-charge of a battery assembly is provided herein. The method includes acquiring with an estimator circuit a sequence of current sensor cell state-of-charges of a sensor cell based on a sensor cell model of the sensor cell and a sequence of sensor voltages across the sensor cell. The sensor cell is coupled in series with the battery assembly, the battery assembly has an assembly battery chemistry, the sensor cell has a sensor battery chemistry, and the assembly battery chemistry is different than the sensor battery chemistry. The method includes calculating a sequence of current battery assembly state-of-charges of the battery assembly based on the sequence of current sensor cell state-of-charges, and calculating an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

In one or more embodiments of the method, the sensor cell model of the sensor cell includes the sequence of current battery assembly state-of-charges as an augmented state variable.

In one or more embodiments of the method, the sequence of current battery assembly state-of-charges is represented by SOC_{BA}(k+1)=(CAP_{SC}/CAP_{BA})(SOC_{SC}(k)−d %)+(Idt/CAP_{BA}))+ε(k). Where SOC_{BA}(k+1) is the current battery assembly state-of-charge at time k+1, k is a plurality of measurement times, CAP_{SC} is a capacity of the sensor cell, CAP_{BA} is a capacity of the battery assembly, SOC_{SC}(k) is the current sensor cell state-of-charge at time k, d % is a minimum charge offset, Idt a sum of a current flowing through the battery assembly, and ε(k) is noise model at the time k

In one or more embodiments of the method, the filtering utilizes an Extended Kalman Filter.

In one or more embodiments of the method, the Extended Kalman Filter is a fast Extended Kalman Filter to calculate the estimated sensor cell state-of-charge.

In one or more embodiments, the method includes estimating a capacity degradation coefficient of the sensor cell using the Extended Kalman Filter executed at a slower rate than the fast Extended Kalman Filter.

In one or more embodiments of the method, the assembly battery chemistry is a lithium iron phosphate chemistry, a lithium iron manganese phosphate chemistry, or a sodium ion chemistry.

In one or more embodiments of the method, the sensor battery chemistry is a nickel manganese cobalt chemistry, a nickel cobalt aluminum chemistry, a lithium-ion manganese chemistry, or a lithium cobalt chemistry.

In one or more embodiments of the method, the sensor cell model includes a hysteresis transit component, a plurality of lagged currents component, a plurality of resistances component, and a terminal voltage component.

A vehicle is provided herein. The vehicle includes a battery assembly, a sensor cell and an estimator circuit. The battery assembly has an assembly battery chemistry. The sensor cell is coupled in series to the battery assembly. The sensor cell has a sensor battery chemistry, and the assembly battery chemistry is different than the sensor battery chemistry. The estimator circuit is coupled to the battery assembly and the sensor cell. The estimator circuit is operational to acquire a sequence of current sensor cell state-of-charges of the sensor cell based on a sensor cell model of the sensor cell and a sequence of sensor voltages across the sensor cell, calculate a sequence of current battery assembly state-of-charges of the battery assembly based on the sequence of current sensor cell state-of-charges, and calculate an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

In one or more embodiments of the vehicle, the estimated battery assembly state-of-charge has an accuracy within 3 percent.

The above features and advantages and other features and advantages of the present disclosure are readily apparent from the following detailed description of the best modes for carrying out the disclosure when taken in connection with the accompanying drawings.

### BRIEF DESCRIPTION OF THE DRAWINGS

FIG. 1 is a schematic plan diagram illustrating a context of a system in accordance with one or more exemplary embodiments.

FIG. 2 is a schematic diagram of a state-of-charge mapping in accordance with one or more exemplary embodiments.

FIG. 3 is a flow diagram of a method for determining an estimated sensor cell state-of-charge and an estimated battery assembly state-of-charge in accordance with one or more exemplary embodiments.

FIG. 4 is a graph of an estimated error for a battery assembly state-of-charge in accordance with one or more exemplary embodiments.

FIG. 5 is a flow diagram of a method for determining an estimated sensor cell state-of-charge and a capacity degradation coefficient of the sensor cell in accordance with one or more exemplary embodiments.

### DETAILED DESCRIPTION

Embodiments of the disclosure provide a sensor cell serially connected to battery assembly (e.g., battery pack or battery module) as a sensing unit to estimate a state-of-charge of the battery assembly. The sensor cell and the battery pack have different chemistries thereby forming a mixed-chemistry system. By incorporating the battery assembly state-of-charge as an augmented state variable into a cell model of the sensor cell, an Extended Kalman Filter (EKF) may be utilized to estimate the state-of-charges of both the sensor cell and the battery assembly in parallel. A closed-loop observer may minimize capacity uncertainties in both chemistries to increase the state-of-charge estimation accuracy for the mixed-chemistry system. The Extended Kalman Filter may be a nonlinear version of a Kalman Filter that linearizes data about an estimate of a current mean.

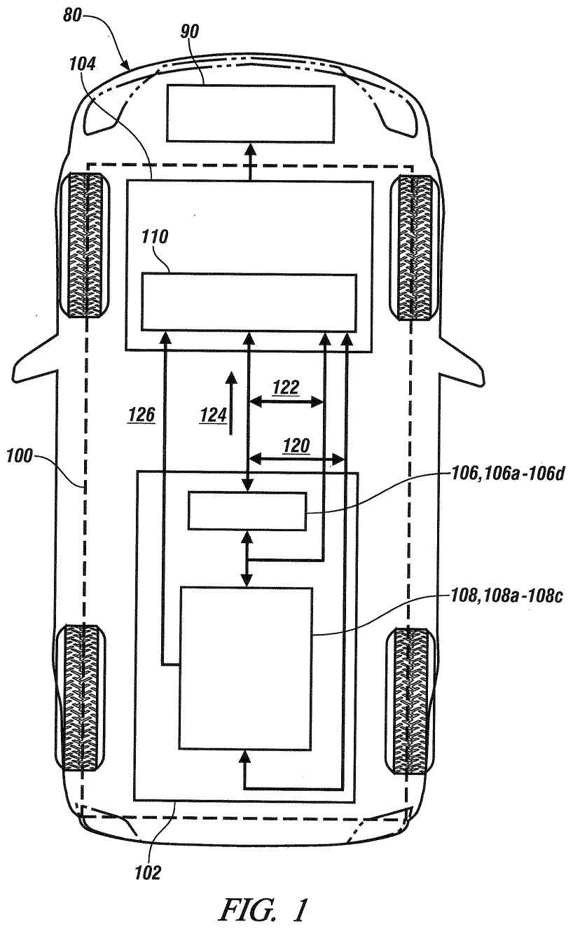

Referring to FIG. 1, a schematic plan diagram illustrating a context of a system is shown in accordance with one or more exemplary embodiments. The system may implement a vehicle 80. The vehicle 80 generally comprises a motor 90 and a system 100. The system 100 includes a rechargeable energy storage system 102 and a controller 104. The rechargeable energy storage system 102 includes one or more sensor cells 106 (one shown) and one or more battery assemblies 108 (one shown). The controller 104 includes an estimator circuit 110.

The rechargeable energy storage system 102 produces a system voltage 120 (e.g., Vt) while charged. The system voltage 120 is measurable by the estimator circuit 110. A sensor voltage 122 (e.g., Vs) is generated by the sensor cell 106 and is measured by the estimator circuit 110. A current 124 (e.g., I) may be presented by rechargeable energy storage system 102 while in a discharging mode. The current 124 may flow into the rechargeable energy storage system 102 while in a charging mode. A correction signal 126 is generated by the battery assembly 108 and presented to the estimator circuit 110. The correction signal 126 conveys a temperature of the battery assembly 108, the system voltage 120 and the current 124 to the estimator circuit 110.

The vehicle 80 may include, but is not limited to, mobile objects such as automobiles, trucks, motorcycles, boats, trains and/or aircraft. In various embodiments, the vehicle 80 may be an electric vehicle. In other embodiments, the vehicle 80 may be a hybrid vehicle. In some embodiments, the vehicle 80 may include stationary objects such as billboards, kiosks and/or marquees. Other types of vehicles 80 may be implemented to meet the design criteria of a particular application.

The motor 90 implements an electric motor. The motor 90 is generally operational to provide rotation and torque to drive wheels of the vehicle 80. The electrical power consumed by the motor 90 may be provided by the rechargeable energy storage system 102 and/or an alternator of the vehicle 80 under the control of the controller 104.

The system 100 implements a high-voltage storage system configured to store electrical energy. The system 100 is electrically coupled to the motor 90. The system 100 is generally operational to provide electrical power to the motor 90 to move the vehicle 80. The system 100 is also operational to be recharged from an electrical source (e.g., charging station and/or on-board alternator). In various embodiments, the system 100 may provide approximately 400 to 800 volts DC (direct current) electrical potential. Other battery voltages may be implemented to meet the design criteria of a particular application.

The rechargeable energy storage system 102 implements a mixed-chemistry battery pack. The rechargeable energy storage system 102 is electrically coupled to the controller 104. While in the discharging mode, the rechargeable energy storage system 102 is operational to provide electrical power to the controller 104 to operate the motor 90. While in the charging mode, the rechargeable energy storage system 102 is operational to receive electrical power through the controller 104 and store the electrical power for later use.

The controller 104 implements a battery controller. The controller 104 is electrically coupled to the motor 90 and to the rechargeable energy storage system 102. The controller 104 is generally operational to transfer electrical power to the rechargeable energy storage system 102 in the charging mode to charge the rechargeable energy storage system 102. The controller 104 may draw electrical power from the rechargeable energy storage system 102 in the discharging mode. The electrical power received from the rechargeable energy storage system 102 may be used to power the motor 90 and/or other loads within the vehicle 80.

The sensor cell 106 implements a battery cell with a sensor battery chemistry. The sensor cell 106 has a sensor cell type. In various embodiments, the sensor cell type of battery may be a nickel manganese cobalt battery, a nickel cobalt aluminum battery, a lithium-ion manganese battery, and/or a lithium cobalt battery. The various sensor cell batteries types have respective battery cell chemistries including a nickel manganese cobalt chemistry 106a, a nickel cobalt aluminum chemistry 106b, a lithium-ion manganese chemistry 106c, and/or a lithium cobalt chemistry 106d. Other battery cell types and/or battery cell chemistries may be implemented to meet a design criteria of a particular application.

The battery assembly 108 implements a battery module and/or a battery pack. The battery module generally includes multiple battery cells. The battery pack includes multiple battery models or multiple battery cells. The battery assembly 108 has a battery assembly type. In various embodiments, the battery assembly type of battery generally includes lithium iron phosphate batteries, lithium iron manganese phosphate batteries, and/or sodium ion batteries. The battery assembly types may have respective battery assembly chemistries including a lithium iron phosphate chemistry 108a, a lithium iron manganese phosphate chemistry 108b, and/or a sodium ion chemistry 108c. Other battery assembly types and/or battery assembly chemistries may be implemented to meet a design criteria of a particular application.

The estimator circuit 110 implements measurement circuitry and calculation circuitry. The estimator circuit 110 is electrically coupled to the battery assembly 108 and the sensor cell 106. The estimator circuit 110 is operational to acquire a sequence of current sensor cell state-of-charges of the sensor cell 106 based on a sensor cell model of the sensor cell 106 and a sequence of the sensor voltages 122 across the sensor cell 106. The estimator circuit 110 may also calculate a sequence of current battery assembly state-of-charges of the battery assembly 108 based on the sequence of current sensor cell state-of-charges, and calculate an estimated battery assembly state-of-charge of the battery assembly 108 and an estimated sensor cell state-of-charge of the sensor cell 106 by filtering in parallel the sequence of current battery assembly state-of-charges and the sequence of current sensor cell state-of-charges. The parallel filtering generally means concurrent filtering, overlapping filtering, in unison filtering, and/or approximately simultaneous filtering.

The system voltage 120 may be a voltage across the rechargeable energy storage system 102. The system voltage 120 is a sum of the sensor voltage 122 of the sensor cell 106 and an assembly voltage of the battery assembly 108. The sensor voltage 122 is a voltage across the sensor cell 106. Both the system voltage 120 and the sensor voltage 122 are measured by the estimator circuit 110.

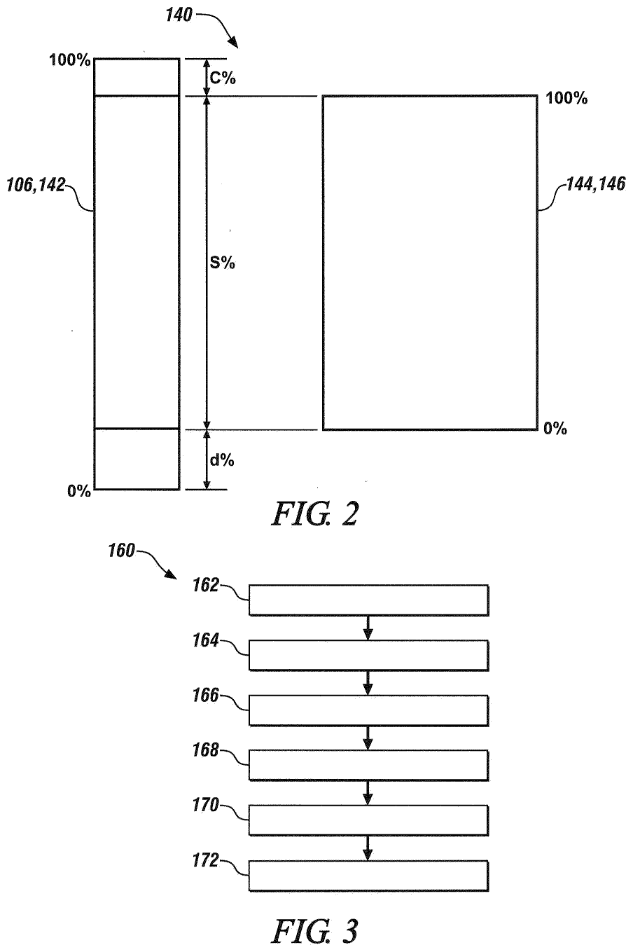

Referring to FIG. 2, a schematic diagram of an example state-of-charge mapping 140 is shown in accordance with one or more exemplary embodiments. The state-of-charge mapping 140 illustrates a sensor cell state-of-charge 142 of the sensor cell 106 relative to a cell state-of-charge 146 of a battery cell 144 having the same battery chemistry as the battery assembly 108. The sensor cell 106 has a sensor cell capacity CAP_{SC}. The battery cell 144 has a battery cell capacity CAP_{BC}. The sensor cell capacity CAP_{SC} is related to the battery cell capacity CAP_{BC} by equation 1 as follows:

$${CAP}_{SC} = \frac{100 \%}{S \%} {CAP}_{BC} \qquad Eq . ( 1 )$$

Where S % is a percentage of the sensor cell capacity CAP_{SC} that spans the full battery cell capacity CAP_{BC} (e.g., from 0% battery cell SOC_{BC} to 100% battery cell SOC_{BC}).

The sensor cell 106 has the sensor cell state-of-charge 142 at a measurement (or observation) k, 142=SOC_{SC}(k). The battery cell 144 has the battery cell state-of-charge 146 at the measurement (or observation) k, 144=SOC_{BC}(k). The sensor cell state-of-charge 142 (SOC_{SC}) is related to the battery cell state-of-charge 146 (SOC_{BC}) by equation 2 as follows:

$${SOC}_{SC} ( k ) = \frac{{CAP}_{BC}}{{CAP}_{SC}} {SOC}_{BC} ( k ) + d \% \qquad Eq . ( 2 )$$

Where d % is a percentage of the sensor cell capacity CAP_{SC} that spans a zero sensor cell state-of-charge SOC_{SC} to a zero battery cell state-of charge SOC_{BC}.

The battery cell 144 may be scaled up to the battery assembly 108 and the battery cell state-of-charge (SOC_{BC}) may be scaled up to the battery assembly state-of-charge (SOC_{BA}). In various embodiments, an augmented state space equation of the battery assembly 108 is represented by equation 3 as follows:

$${SOC}_{BA} ( k + 1 ) = ( {CAP}_{SC} / {CAP}_{BA} ) ( {SOC}_{SC} ( k ) - d \% ) + ( Idt / {CAP}_{BA} ) + ε ( k ) \qquad Eq . ( 3 )$$

Where SOC_{BA}(k+1) is the current battery assembly state-of-charge at time k+1, k is a sequence of measurement times, CAP_{SC} is a capacity of the sensor cell, CAP_{BA} is a capacity of the battery assembly, SOC_{SC}(k) is the current sensor cell state-of-charge at time k, d % is a minimum charge offset, Idt is a sum of a current flowing through the battery assembly 108, and ε(k) is noise model at the time k.

A sensor cell model of the sensor cell 106 may be modeled as a hysteresis transit component, a lagged current component, and a resistances component. A short-hand notation may be used for the state-of-charge (SOC) and is defined in equation 4 as follows:

$$θ = SOC \qquad Eq . ( 4 )$$

A derivative (\dot{θ}_{SC}) of the sensor cell state-of-charge may (SOC_{SC}) be expressed by equation 5 as follows:

$${\dot{θ}}_{SC} = \frac{I}{{CAP}_{SC}} \qquad Eq . ( 5 )$$

The hysteresis transit component ( [symbol] ) may be expressed by equation 6 as follows:

$$\dot{ς} = \frac{I}{{k}_{hys} {CAP}_{SC}} ( 1 - sign ( I ) ς ) \qquad Eq . ( 6 )$$

The lagged currents component (uᵢ) may be expressed by equation 7 as follows:

$${τ}_{i} {\dot{u}}_{i} = - {u}_{i} + \frac{I}{{I}^{*}} , for I = 1 , … , n \qquad Eq . ( 7 )$$

Where τᵢ is the lag time constant, I is the current flowing through the sensor cell 106, and I* is a scale factor.

The resistances component (\dot{R}ᵢⱼ) may be expressed by equation 8 as follows:

$${\dot{R}}_{ij} = \frac{\partial }{\partial θ} {R}_{ij}^{tab} ( {θ}_{SC} , T ) \frac{I}{{Cap}_{SC}} , for i ∈ \{ 1 , … , n , Ω \} \qquad Eq . ( 8 )$$

Where T is temperature. A resulting terminal voltage (e.g., Vs) of the sensor cell 106 (see FIG. 1) may be expressed by equation 9 as follows:

$$Vs = OCV ( {θ}_{SC} ) + ς {V}_{gap} ( T ) + {\sum }_{i = 1}^{n} {\sum }_{j = 1}^{{m}_{i}} {R}_{ij} {f}_{ij} ( {u}_{i} , T , {θ}_{SC} ) + {\sum }_{j = 1}^{{m}_{Ω}} {R}_{{Ω}_{j}} {f}_{{Ω}_{j}} ( I / {I}^{*} , T , {θ}_{SC} ) \qquad Eq . ( 9 )$$

Where OCV(θ_{SC}) is an open-circuit voltage, [symbol] V_{gap}(T) is a hysteresis, Σᵢ₌₁ⁿΣⱼ₌₁^{m}^{ᵢ}Rᵢⱼfᵢⱼ(uᵢ, T, θ_{SC}) is a diffusion/transport factor, Σⱼ₌₁^{m}^{_{Ω}}R_{Ωj}f_{Ωj}(I/I*, T, θ_{NCM}) are ohmic/reaction kinetics, and Vgap is a remaining voltage difference after relaxation of the sensor cell 106.

Since the observation equation 3 is modeled, uncertainty in the battery assembly capacity is modeled as process noise ε(k). The process noise may be rejected by an Extended Kalman Filter (EKF). The Extended Kalman Filter is generally applied to estimate the sensor cell state-of-charge SOC_{SC} and the battery assembly state-of-charge SOC_{BA} in parallel (or concurrently, overlapping, in unison, and/or approximately simultaneous).

In a generally nonlinear form of the sensor cell model, equation 5 for the sensor cell 106 may be written as equation 10 as follows:

$${\dot{θ}}_{SC} = g ( {u}_{i} , \frac{I}{{CAP}_{SC}} ) \qquad Eq . ( 10 )$$

Where \dot{u}ᵢ=fᵢ(uᵢ, I), for i=1, . . . , n (hysteresis, diffusion, electrode/solid-electrolyte interphase (SEI) potential, etc.). The terminal voltage of equation 9 may be written as equation 11 as follows:

$$Vs = OCV ( {θ}_{SC} ) + φ ( {u}_{i} , {θ}_{SC} , I , T ) + {\sum }_{j = 1}^{{m}_{Ω}} {R}_{{Ω}_{j}} {f}_{{Ω}_{j}} ( I ) \qquad Eq . ( 11 )$$

The general nonlinear model may include various battery models, equivalent circuits, or electrochemical models.

Referring to FIG. 3, with reference back to FIG. 1, a flow diagram of an example method 160 for determining an estimated sensor cell state-of-charge and an estimated battery assembly state-of-charge is shown in accordance with one or more exemplary embodiments. The method 160 may be implemented in the estimator circuit. The method (or process) 160 generally includes steps 162 to 172, as illustrated. The sequence of steps is shown as a representative example. Other step orders may be implemented to meet the criteria of a particular application.

In the step 162, the sensor cell model may be determined. The system voltage 120 (Vs), the sensor voltage 122 (Vs), and the current 124 (I) may be acquired multiple times (e.g., k observations) in the step 164. In the step 166 the sensor voltage 122 is used to determine the current sensor cell state-of-charge SOC_{SC} and the current battery assembly state-of-charge SOC_{BA} at each observation. The augmented state is calculated in the step 168.

In the step 170 an Extended Kalman Filter is applied in parallel to sets of the current sensor cell state-of-charge SOC_{SC} and the current battery assembly state-of-charge SOC_{BA} at the observations to calculate an estimated sensor cell state-of-charge [symbol] and an estimated battery assembly state-of-charge [symbol] . The estimated sensor cell state-of-charge [symbol] and the estimated battery assembly state-of-charge [symbol] may be stored in the estimator circuit 110 in the step 172 for subsequent use.

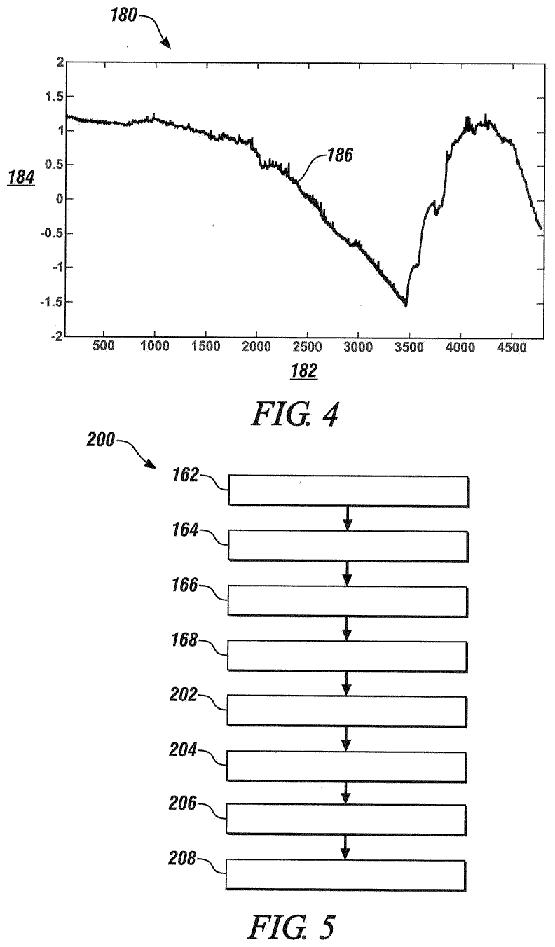

Referring to FIG. 4, a graph 180 of an example estimated error for a battery assembly state-of-charge is shown in accordance with one or more exemplary embodiments. The graph 180 generally includes a time axis 182 and an error axis 184. The time axis 182 may be in units of second. The error axis 184 may be in units of an error percentage. A curve 186 illustrates the estimate error in the battery assembly state-of-charge estimation over time. The curve 186 generally illustrates that the error percentage is less than 1.5% from zero error.

Referring to FIG. 5, with reference back to FIG. 1, a flow diagram of an example method 200 for determining an estimated sensor cell state-of-charge and a capacity degradation coefficient of the sensor cell is shown in accordance with one or more exemplary embodiments. The method 200 may be implemented in the estimator circuit 110. The method (or process) 200 generally includes steps 162 to 168 and 202 to 208, as illustrated. The sequence of steps is shown as a representative example. Other step orders may be implemented to meet the criteria of a particular application.

The steps 162 to 168 may be the same steps as illustrated in the method 160. Once the signals have been measured over multiple observations, a fast Extended Kalman Filter is applied in the step 202 to the observed measurements. In the step 204, the estimated sensor cell state-of-charge [symbol] may using the fast Extended Kalman Filter and equations 12, 13, and 14 as follows:

$$q ( k + N ) = q ( k ) + ε ( k ) \qquad Eq . ( 12 )$$

$${θ}_{SC} ( k + N ) = {θ}_{SC} ( k ) + \frac{q {\int }_{0}^{N \cdot dt} idt}{{Cap}_{SC 0}} \qquad Eq . ( 13 )$$

$$( k ) = {θ}_{SC} ( k ) \qquad Eq . ( 14 )$$

Where q is the capacity degradation coefficient, and N is an elapsed time interval. In the step 206 a slow Extended Kalman Filter is applied to estimate the sensor cell capacity degradation coefficient q. The “slow” Extended Kalman Filter means that one or a few observations are used in each filter cycle (or duration). The “fast” Extended Kalman Filter means that the observations in the elapsed time interval are used in each filter cycle. In other words, the slow Extended Kalman Filter is executed as a lower rate than the fast Extended Kalman Filter. In the step 208, the estimated sensor cell state-of-charge and the sensor cell capacity degradation coefficient are stored in the estimator circuit 110 for later use.

Various embodiments of the system 100 generally utilize the sensor cell 106 as sensing unit to estimate the battery assembly state-of-charge of LFP. A cell model of the sensor cell 106 is formulated with the battery assembly state-of-charge as an augmented state variable in the plant model. The system 100 applies the Extended Kalman Filter to estimate the state-of-charges of both the sensor cell 106 and the battery assembly simultaneously (or in parallel). The system 100 covers various types of battery cell models and applies the Extended Kalman Filter to estimate mixed-chemistry state-of-charges. A two-time scale Extended Kalman Filter (e.g., fast and slow observers) may be used to determine both the estimated sensor cell state-of-charge and the sensor cell capacity degradation coefficient. The system 100 also provide estimated battery assembly state-of-charge accuracy within 3% with a minimum software change from existing battery management system techniques. The improved accuracy enables low-cost electric vehicles with better performances.

Embodiments of the disclosure generally provide a system for estimating a state-of-charge of a battery assembly. The system includes a sensor cell, a battery assembly, and an estimator circuit. The sensor cell is coupled in series to the battery assembly. The battery assembly has an assembly battery chemistry, the sensor cell has a sensor battery chemistry, and the assembly battery chemistry is different than the sensor battery chemistry. The estimator circuit is coupled to the battery assembly and the sensor cell. The estimator circuit is operational to: acquire a sequence of current sensor cell state-of-charges based on a sensor cell model and a sequence of sensor voltages across the sensor cell; calculate a sequence of current battery assembly state-of-charges based on the sequence of current sensor cell state-of-charges; and calculate an estimated battery assembly state-of-charge and an estimated sensor cell state-of-charge by filtering in parallel the sequence of current battery assembly state-of-charges and the sequence of current sensor cell state-of-charges.

Numerical values of parameters (e.g., of quantities or conditions) in this specification, including the appended claims, are to be understood as being modified in each instance by the term “about” whether or not “about” actually appears before the numerical value. “About” indicates that the stated numerical value allows some slight imprecision (with some approach to exactness in the value; about or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of values and further divided ranges within the entire range. Each value within a range and the endpoints of a range are hereby disclosed as a separate embodiment.

While the best modes for carrying out the disclosure have been described in detail, those familiar with the art to which this disclosure relates will recognize various alternative designs and embodiments for practicing the disclosure within the scope of the appended claims.

What is claimed is:

1. A system for estimating a state-of-charge of a battery assembly, the system comprising:
a sensor cell coupled in series to the battery assembly, wherein the battery assembly has an assembly battery chemistry, the sensor cell has a sensor battery chemistry, and the assembly battery chemistry is different than the sensor battery chemistry; and
an estimator circuit coupled to the battery assembly and the sensor cell, wherein the estimator circuit is operational to:
acquire a sequence of current sensor cell state-of-charges of the sensor cell based on a sensor cell model of the sensor cell and a sequence of sensor voltages across the sensor cell;
calculate a sequence of current battery assembly state-of-charges of the battery assembly based on the sequence of current sensor cell state-of-charges; and
calculate an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

2. The system according to claim 1, wherein the sensor cell model of the sensor cell includes the sequence of current battery assembly state-of-charges as an augmented state variable.

3. The system according to claim 2, wherein the sequence of current battery assembly state-of-charges is represented by:
$${SOC}_{BA} ( k + 1 ) = ( {CAP}_{SC} / {CAP}_{BA} ) ( {SOC}_{SC} ( k ) - d \% ) + ( Idt / {CAP}_{BA} ) ) + ε ( k ) ,$$
wherein SOC_{BA}(k+1) is the current battery assembly state-of-charge at time k+1, k is a plurality of measurement times, CAP_{SC} is a capacity of the sensor cell, CAP_{BA} is a capacity of the battery assembly, SOC_{SC}(k) is the current sensor cell state-of-charge at time k, d % is a minimum charge offset, Idt is a sum of a current flowing through the battery assembly, and ε(k) is noise model at the time k.

4. The system according to claim 1, wherein the filtering utilizes an Extended Kalman Filter.

5. The system according to claim 4, wherein the Extended Kalman Filter is a fast Extended Kalman Filter to calculate the estimated sensor cell state-of-charge.

6. The system according to claim 5, wherein the estimator circuit is further operational to estimate a capacity degradation coefficient of the sensor cell using the Extended Kalman Filter executed at a slower rate than the fast Extended Kalman Filter.

7. The system according to claim 1, wherein the assembly battery chemistry is a lithium iron phosphate chemistry, a lithium iron manganese phosphate chemistry, or a sodium ion chemistry.

8. The system according to claim 1, wherein the sensor battery chemistry is a nickel manganese cobalt chemistry, a nickel cobalt aluminum chemistry, a lithium-ion manganese chemistry, or a lithium cobalt chemistry.

9. The system according to claim 1, wherein the battery assembly is a battery pack or a battery module.

10. A method for estimating a state-of-charge of a battery assembly, comprising:
acquiring with an estimator circuit a sequence of current sensor cell state-of-charges of a sensor cell based on a sensor cell model of the sensor cell and a sequence of sensor voltages across the sensor cell, wherein the sensor cell is coupled in series with the battery assembly, the battery assembly has an assembly battery chemistry, the sensor cell has a sensor battery chemistry, and the assembly battery chemistry is different than the sensor battery chemistry;
calculating a sequence of current battery assembly state-of-charges of the battery assembly based on the sequence of current sensor cell state-of-charges; and
calculating an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

11. The method according to claim 10, wherein the sensor cell model of the sensor cell includes the sequence of current battery assembly state-of-charges as an augmented state variable.

12. The method according to claim 11, wherein the sequence of current battery assembly state-of-charges is represented by:
$${SOC}_{BA} ( k + 1 ) = ( {CAP}_{SC} / {CAP}_{BA} ) ( {SOC}_{SC} ( k ) - d \% ) + ( Idt / {CAP}_{BA} ) ) + ε ( k ) ,$$
wherein SOC_{BA}(k+1) is the current battery assembly state-of-charge at time k+1, k is a plurality of measurement times, CAP_{SC} is a capacity of the sensor cell, CAP_{BA} is a capacity of the battery assembly, SOC_{SC}(k) is the current sensor cell state-of-charge at time k, d % is a minimum charge offset, Idt a sum of a current flowing through the battery assembly, and ε(k) is noise model at the time k.

13. The method according to claim 10, wherein the filtering utilizes an Extended Kalman Filter.

14. The method according to claim 13, wherein the Extended Kalman Filter is a fast Extended Kalman Filter to calculate the estimated sensor cell state-of-charge.

15. The method according to claim 14, further comprising:
estimating a capacity degradation coefficient of the sensor cell using the Extended Kalman Filter executed at a slower rate than the fast Extended Kalman Filter.

16. The method according to claim 10, wherein the assembly battery chemistry is a lithium iron phosphate chemistry, a lithium iron manganese phosphate chemistry, or a sodium ion chemistry.

17. The method according to claim 10, wherein the sensor battery chemistry is a nickel manganese cobalt chemistry, a nickel cobalt aluminum chemistry, a lithium-ion manganese chemistry, or a lithium cobalt chemistry.

18. The method according to claim 10, wherein the sensor cell model includes a hysteresis transit component, a plurality of lagged currents component, a plurality of resistances component, and a terminal voltage component.

19. A vehicle comprising:
a battery assembly having an assembly battery chemistry;
a sensor cell coupled in series to the battery assembly, wherein the sensor cell has a sensor battery chemistry, and the assembly battery chemistry is different than the sensor battery chemistry; and
an estimator circuit coupled to the battery assembly and the sensor cell, wherein the estimator circuit is operational to:
acquire a sequence of current sensor cell state-of-charges of the sensor cell based on a sensor cell model of the sensor cell and a sequence of sensor voltages across the sensor cell;
calculate a sequence of current battery assembly state-of-charges of the battery assembly based on the sequence of current sensor cell state-of-charges; and
calculate an estimated battery assembly state-of-charge of the battery assembly and an estimated sensor cell state-of-charge of the sensor cell by filtering in parallel the sequence of current battery assembly state-of-charges and the sequence of current sensor cell state-of-charges.

20. The vehicle according to claim 19, wherein the estimated battery assembly state-of-charge has an accuracy within 3 percent.
